(19) United States
(12) Patent Application Publication
(10) Pub. No.: US 2005/0020000 A1
(43) Pub. Date: Jan. 27, 2005

(54) Transistor manufacturing method, electro-optic device and electronic instrument

(75) Inventor: Ichio Yudasaka, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/859,126

(22) Filed: Jun. 3, 2004

(30) Foreign Application Priority Data
Jul. 9, 2003 (JP) 2003-194242

(51) Int. Cl. H01L 21/8238; H01L 27/01

(52) U.S. Cl. 438/199

(57) ABSTRACT

In a transistor having a top gate structure, a portion of a gate insulating film is formed using a coating method. At this time, the size of the semiconductor film on which the coating film is formed is appropriately set to correspond to the properties of the coating liquid, the coating conditions, and the film thickness required in the coating film. Electrical characteristics and reliability of a transistor are improved.

### BACKGROUND OF THE INVENTION

1. Field of the Invention

Priority is claimed on Japanese Patent Application No. 2003-194242, filed Jul. 9, 2003, the content of which is incorporated herein by reference.

The present invention relates to a technology for manufacturing a transistor.

2. Description of Related Art

In a process for manufacturing a semiconductor device, flattening the film surface thereof is extremely important in order to prevent breakages and short circuiting of wires and the like that are formed on the film surface. In particular, in a transistor, the degree of uniformity of the film thickness of the gate insulating film has a considerable effect on the electrical characteristics of the transistor. Therefore, technology is demanded that enables this gate insulating film to be formed more flatly.

Conventionally, gate insulating films of transistor have been formed using mainly a CVD method (see, for example, Japanese Patent Application Unexamined Publication Nos. 8-181325 and 10-144929).

However, in a conventional transistor, problems occur such as the gate pressure resistance being insufficient or the leak current being too great. These problems are mainly caused by the ability of a CVD film to form a coating on bumps and indentations on a substrate surface. For example, in a top gate type of transistor, because a gate insulating film is formed on top of a patterned silicon film (i.e., on a semiconductor film), then at the least, a step portion (i.e., a difference in level) created by the film thickness of the semiconductor film itself is formed on the substrate. Moreover, in the semiconductor film patterning step, because a portion of the silicon oxide or silicon nitride, which is the base insulating film thereof, is also etched, a further step portion is formed on the substrate corresponding to the amount of the etching. The size of the overall step portion is increased if these two step portions are superposed. If a gate insulating film is formed using a CVD method on such a step portion, then portions where the gate insulating film is thin are formed on the top end portion and side ends of the semiconductor film, so that problems such as a deterioration in the gate pressure resistance and an increase in the leak current and the like are brought about.

Furthermore, in a CVD method, foreign matter such as particles and the like are sometimes created. This tends to create still more deterioration in the gate pressure resistance and a greater increase in the leak current, or else causes shorting defects between a gate electrode and a source or drain.

The present invention was conceived in order to solve the aforementioned problems and it is an object thereof to provide a transistor manufacturing method that enables a highly reliable transistor that has excellent electrical characteristics to be manufactured, and an electro-optic device and electronic instrument that are provided with this transistor.

### SUMMARY OF THE INVENTION

In order to achieve the above object, according to an aspect of the present invention, there is provided a method of manufacturing a transistor comprising the steps of: forming a semiconductor film over a substrate; patterning the semiconductor film in an island configuration; forming a gate insulating film on the semiconductor film; and forming a gate electrode on the gate insulating film, wherein forming the gate insulating film comprises forming a first insulating film that constitutes at least a portion of the gate insulating film by a coating method.

In this method, because the first insulating film is a coated film, differences in level caused by the film thickness of the semiconductor film itself, as well as differences in level occurring when the base insulating film is cut away in the patterning step and the like can be flattened by the insulating film. As a result, the film thickness uniformity of the gate insulating film is improved, and a transistor that has high pressure resistance and little current leakage is obtained. Moreover, because no foreign matter such as particles and the like are generated in a coating method, the reliability of the transistor is improved. Note that, in the first insulating film forming step, a variety of methods such as a spin coating method, a dip coating method, a role coating method, a curtain coating method, a spray method, or a droplet discharge method (such as an inkjet method) may be used. In a spin coating method, in particular, because the liquid film is spread over the interior of the substrate surface by centrifugal force, a flatter film can be easily formed.

In addition, it is possible to use as the coating liquid the original material of the insulating film and a precursor thereof or a variety of liquid materials that can be converted into the first insulating film by heat processing. Specifically, a material obtained by dissolving polysilazane or spin on glass (SOG) or the like in a solvent such as xylene is used as the coating liquid. This is then converted into silicon oxide by heat processing so that a high quality gate insulating film can be formed. In particular, polysilazane has greater crack resistance compared to other materials and forms an insulating film having fewer residual impurities. Note that it is desirable that the heat processing of the polysilazane is performed in a WET O₂ atmosphere (i.e., in an oxygen atmosphere that contains water vapor). As a result, it is possible to reduce nitrogen components in the insulating film, which are a cause of polarization, and to stabilize the electrical characteristics of the transistor.

In the first insulating film forming step, some unevenness is created in the flow resistance of the coating liquid by bumps and indentations in the substrate. For example, the flow resistance of the coating liquid is relatively greater in areas where the semiconductor film is formed than in other areas, and there may be cases in which swelling is created in the film surface at these portions. The size of such swelling varies depending not only on the film thickness of the coating film (namely, the film thickness of the first insulating film), the properties of the coating liquid (i.e., the viscosity and the like), and the coating conditions, but also on the size of the semiconductor film on which this coating film is formed. Namely, the film thickness uniformity of the gate insulating film is closely related not only to the first insulating film forming step, but also to the semiconductor film patterning step, which is the step prior to the first insulating film forming step. In order to obtain a uniform film, it is desirable beforehand in the semiconductor film patterning step to set the pattern size to the optimum size to correspond to the properties of the coating liquid that is used in the subsequent step, as well as to the coating conditions thereof and also the film thickness required in the first insulating film.

This specific procedure involves, firstly, determining the overall size of the semiconductor film and the film thickness of the gate insulating film in accordance with the performance required in the transistor. Next, the film thickness required for the first insulating film is determined in accordance with the film thickness of the gate insulating film, and the properties (i.e., the viscosity and the like) of the coating liquid and the coating conditions are determined in order that this film thickness can be obtained. Once these conditions have been determined, the maximum size of the semiconductor film is determined, for example, from experimental data or the like such that swelling of the film surface of the coating liquid does not occur, or such that, if it does occur, it is within allowable limits. Therefore, the pattern size of the semiconductor film may be set within this size range. For example, if the overall size of the semiconductor film is greater than the aforementioned maximum size, the semiconductor film is divided into a plurality of portions. By making the size of each semiconductor film smaller (namely, less than or equal to the aforementioned maximum size) in this way with the transistor having a multigate structure, the gate insulating film that is formed on top of the semiconductor film can be flattened still further.

In addition, in the gate insulating film forming step, it is desirable that a step be provided for forming a second insulating film that constitutes a portion of the gate insulating film by oxidizing the surface of the semiconductor film before the first insulating film forming step. In a transistor, in addition to the film quality and film thickness uniformity of the gate insulating film, the boundary face characteristics of the gate insulating film have a considerable effect on the electrical characteristics of the transistor. Therefore, by providing a surface oxidized film that gives better boundary face characteristics than the first insulating film, which is a coating film, at a boundary face with the semiconductor film, an improvement in the performance of the transistor can be achieved.

An example of a method of forming the second insulating film is a method in which the surface of the semiconductor film is plasma processed using, for example, a gas that contains oxygen as the processing gas. Instead of this, it is also possible to heat the semiconductor film in an ozone gas atmosphere. In this method, ozone is decomposed in the vicinity of the heated semiconductor film so that oxygen radicals are generated. The surface of the semiconductor film is oxidized by these oxygen radicals that are in an active state so that an oxidized film is formed. Therefore, it is also possible to obtain a high quality boundary face with little film surface damage, and to simplify the apparatus and shorten the processing time, by employing a method that uses plasma.

Moreover, in the above described gate insulating film forming step, it is also possible to provide a step in which a third insulating film that constitutes a portion of the gate insulating film is formed by vapor deposition at a boundary face with the semiconductor film or at a boundary face with the gate electrode. Excellent boundary face characteristics can also be obtained by providing this step. Note that the third insulating film may be formed at only one of the boundary face with the semiconductor film and the boundary face with the gate electrode, or may be formed at both boundary faces.

The electro-optic device of the present invention comprises a transistor manufactured using the method described above. The electronic instrument of the present invention comprises this electro-optic device. As a result, a high-performance electro-optic device and electronic instrument can be provided.

### BRIEF DESCRIPTION OF THE DRAWINGS

FIGS. 1A and 1B are views showing the structure of principal portions of a liquid crystal device according to an embodiment of the present invention.

FIG. 2 is a flow chart for describing a transistor manufacturing procedure according to an embodiment of the present invention.

FIG. 3 is a process diagram describing a transistor manufacturing method according to an embodiment of the present invention.

FIGS. 4A and 4B are a process diagram continuing on from FIG. 3.

FIGS. 5A to 5C are a process diagram continuing on from FIGS. 4A and 4B.

FIGS. 6A to 6C are a process diagram continuing on from FIGS. 5A to 5C.

FIG. 7 is a view showing an example of the electronic instrument of the present invention.

FIGS. 8A and 8B are a view for describing the effects of the size of a semiconductor film relative to the film thickness uniformity of a gate insulating film.

### DETAILED DESCRIPTION OF THE INVENTION

A liquid crystal device will now be described as an example of the electro-optic device of the present invention with reference made to the drawings. Note that in all of the drawings described below, in order to simplify understanding of the drawings, the proportions of the film thickness and dimensions of each component element and the like have been altered where appropriate.

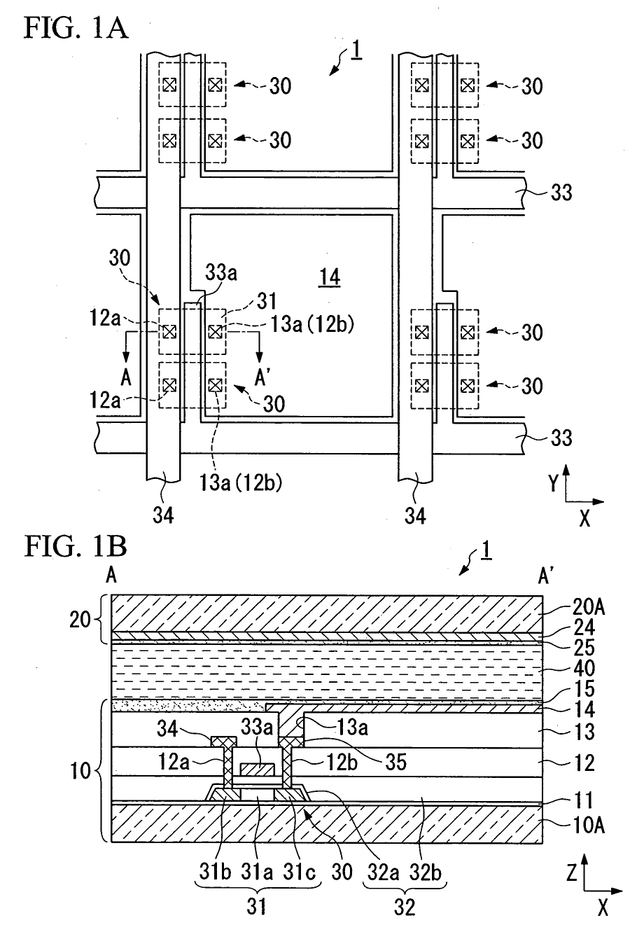

As is shown in FIG. 1, a liquid crystal device 1 of the present embodiment is constructed by an active matrix substrate 10, an opposing substrate 20, and a liquid crystal layer 40 that serves as an optical modulation layer and is held between the substrates 10 and 20.

FIG 1A is a plan view showing the structure of principal portions of the active matrix substrate 10.

On the substrate 10, a plurality of scan wires 33 and signal wires 34 are provided running in an X direction and Y direction respectively on a substrate body 10A formed from glass or plastic or the like. A pixel electrode 14 is positioned in each pixel bounded by the wires 33 and 34. A plurality (two in the present embodiment) of TFT (i.e., thin-film transistors) 30 are provided in each pixel to perform electrification control of the pixel electrode 14. Namely, two island-shaped semiconductor films 31 that run alongside the signal wires 34, and also a common gate electrode 33a that covers both semiconductor films 31 are provided in the vicinity of intersecting portions between the scan wires 33 and the signal wires 34. The configuration of a gate electrode 33a is such that it branches from one scan wire 33 out towards the previous scan wire. Areas of the semiconductor films 31 that face the gate electrode 33a function as channel portions, and opposing portions on the left and right on either side of the channel portions respectively form source portions and drain portions. The source portion of each semiconductor film 31 is electroconductively connected to a signal wire 34 via a contact hole 12a. The drain portion of each semiconductor film 31 is electroconductively connected to a pixel electrode 14 via contact holes 12b and 13a.

FIG. 1B is a view showing the structure along a cross-section A-A′ shown in FIG. 1A.

The TFT 30 of the present embodiment has a top gate type of structure, and is formed by a semiconductor film 31, a gate insulating film 32, and a gate electrode 33a stacked in that order from the bottom layer side of the substrate 10A that forms a base.

Namely, the gate insulating film 32 is provided so as to cover the entire substrate surface on a semiconductor film 31 that is formed in an island configuration on a base insulating film 11, and the gate electrode 33a is provided on the gate insulating film 32 facing the semiconductor film 31. In addition, an interlayer insulating film 12 is provided on the 20 substrate 10A so as to cover the gate insulating film 32 and the gate electrode 33a. A signal wire 34 and an intermediate layer 35 are provided on the insulating film 12. A contact hole 12a that communicates with a source portion 31b of the semiconductor film 31, and a contact hole 12b that communicates with a drain portion 31c of the semiconductor film 31 are provided in the insulating film 12. The signal wire 34 and the intermediate layer 35 are electroconductively connected respectively to the aforementioned source portion 31b and drain portion 31c via the contact holes 12a and 12b. Furthermore, an interlayer insulating film 13 is provided on the substrate 10A so as to cover the interlayer insulating film 12, the signal wires 34, and the intermediate layer 35. The pixel electrode 14 is provided on this insulating film 13. An oriented film 15 formed by polyimide or the like is also provided on the substrate which is structured as described above so as to cover the pixel electrode 14 and the interlayer insulating film 13.

In contrast, in the opposing substrate 20, a translucent common electrode 24 formed from ITO or the like is provided on a substrate body 20A formed by a translucent substrate such as glass or plastic. An oriented film 25 formed by polyimide or the like is further provided on the electrode 24.

The aforementioned gate insulating film 32 has a two layer structure having an insulating film 32a that covers a surface of the island-shaped semiconductor film 31, and an insulating film 32b that is stacked on top of the insulating film 32a. The insulating film 32a may be obtained, for example, by forming silicon oxide or silicon nitride or the like using a vapor deposition method such as a PECVD method or sputter method. Alternatively, it is also possible to oxidize the surface of the semiconductor film 31. Examples of this method include a method in which plasma processing is performed on the surface of the semiconductor film 31 using, for example, a gas that contains oxygen as the processing gas, and a method in which ultraviolet light is irradiated onto a semiconductor film in an oxygen-containing gas atmosphere. Either of these methods enables an excellent boundary face with the semiconductor film 31 to be formed, and contributes to an improved performance in the transistor. Note that, in the present embodiment, a method in which surface oxidation is performed by ultraviolet irradiation is employed as the method of forming the insulating film 32a.

The original material of the insulating film and a precursor thereof, or a material obtained by dissolving in a solvent a material that can be converted into an insulating film by heat processing is used as the coating liquid. The insulating film 32b is formed by coating this coating liquid on a substrate.

A polysilazane (a generic term for high polymers having a Si—N bond), for example, can be used as this coating liquid. A polysilazane can be converted into silicon oxide by being mixed in a liquid such as xylene and then coated on a substrate, which is then heat processed in an atmosphere containing water vapor or oxygen. One polysilazane is [SiH₂NH]ₙ (wherein n is a positive integer), which is known as polyperhydrosilazane. This product is marketed by “Tonen Kabushikikaisha” under the trade name of “Tonen Polysilazane”. Note that if the H in the [SiH₂NH]ₙ is substituted by an alkyl group (for example, a methyl group or an ethyl group), it becomes an organic polysilazane, which may be differentiated from an inorganic polysilazane.

Spin on glass (SOG) can be used as a liquid material that forms an insulating film by undergoing heat processing after being coated. This SOG is a polymer having a siloxane bond as the basic structure thereof, and there are organic SOG that has an alkyl base and inorganic SOG that does not have an alkyl base. Alcohol or the like is used as the solvent for the SOG. An SOG film is used as an interlayer insulating film for LSI for flattening purposes. An organic SOG film is easily etched by oxygen plasma processing, while an inorganic SOG film has the drawback that cracks are easily generated therein even when the film has a film thickness of several hundred nm. Consequently, as a single layer, it is almost never used for an interlayer insulating film, and is used as a flattening layer above a CVD insulating film. In contrast, polysilazane is highly resistant to cracking, and is resistant to oxygen plasma, and, even as a single layer, is capable of being used as a reasonably thick insulating layer. In addition, polysilazane is able to form an insulating film of excellent quality that leaves few residual impurities compared with other materials. Accordingly, in this example, a material obtained by mixing polysilazane in xylene is used as the coating liquid.

A variety of methods such as a spin coating method, a dip coating method, a role coating method, a curtain coating method, a spray method, or a droplet discharge method (such as an inkjet method) may be used as the coating method. In a spin coating method, in particular, because the coating liquid is drawn over the interior of the substrate surface by centrifugal force when it is being formed, a more uniform film can be easily formed. Therefore, in the present example, a spin coating method is used as the coating method.

In this manner, if a portion of the gate insulating film 32 is formed using a coating method, due to the fluidity of the coating solution the insulating film 32b is formed levelly in a form that evens out bumps and indentations in the substrate surface. As a result, the film thickness uniformity of the gate insulating film 32 in the region where the semiconductor film 31 is formed is greater compared with a conventional film formed by a CVD method.

However, in a coating method, because the flow resistance of the coating liquid is changed by the bumps and indentations in the substrate surface, there are cases in which a slight amount of non-uniformity is generated in the film thickness. Namely, because the insulating film 32b is formed so as to even out steps (i.e., differences in level) created by the patterning of the semiconductor film 31, as is shown in FIG. 8A, in a semiconductor film 31 formation area E1 where the step is formed, the film thickness L2 of the coating film M is thinner than the film thickness L1 of the coating film M in a semiconductor film 31 non-formation area E2. In this portion, the flow resistance of the coating solution increases relatively. Therefore, if there is a large difference in the flow resistances of the two areas E1 and E2, or if there is a wide step surface, then, as is shown in FIG. 8B, a large swelling g is created in the film surface of the insulating film 32b in the semiconductor film 31 formation area E1, creating an obstacle to the operation of the transistor. Accordingly, it is necessary to restrict this type of film thickness non-uniformity in the insulating film 32b to a fixed range. However, the size of this swelling in the film surface is changed not only by the difference in film thicknesses (i.e., L1-L2) of the coating film M that is formed in the two areas E1 and E2, by the composition (viscosity and the like) of the coating liquid, and by the coating conditions, but also by the size W of the semiconductor film 31. Therefore, in the patterning step of the semiconductor film 31, it is necessary to set the pattern size to the optimum in accordance with the composition of the coating liquid used in the subsequent insulating film 32b formation step, the coating conditions thereof, and the film thickness required in the insulating film 32b.

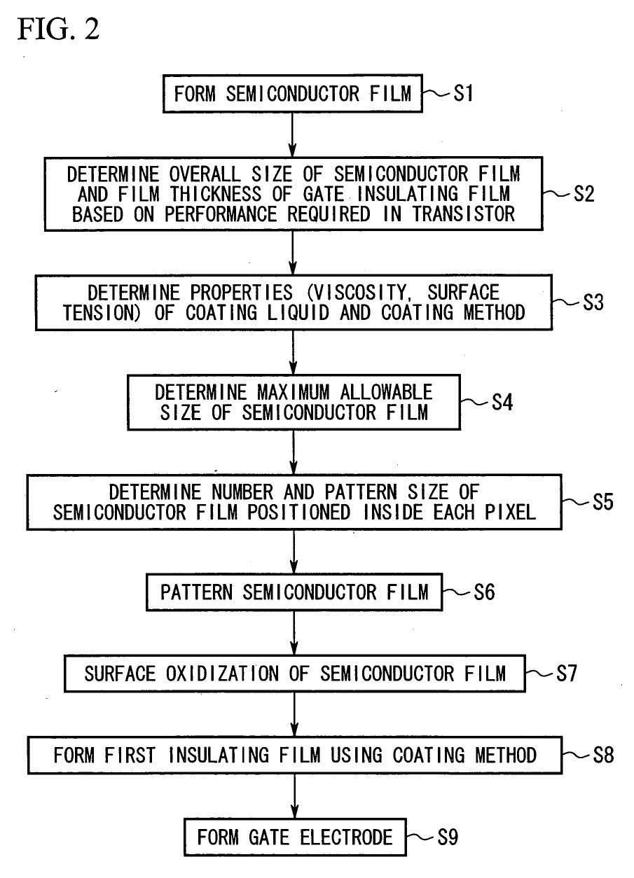

As is shown in FIG. 2, the specific manufacturing procedure involves, firstly, forming a semiconductor film on the entire surface of a substrate (step S1; semiconductor film formation step). Next, this semiconductor film is patterned so that island-shaped semiconductor films are formed in each pixel (semiconductor film patterning step).

At this time, firstly, the overall size of the semiconductor film placed inside a single pixel and the film thickness of the gate insulating film are determined based on the properties required in the transistor (step S2). Next, the film thickness required in the insulating film 32b is determined in accordance with the film thickness of this gate insulating film, and the composition of the coating liquid and the coating conditions are set such that this film thickness can be obtained (step S3). Once these conditions have been set, the maximum size of the semiconductor film is determined, for example, from experimental data or the like such that no swelling occurs in the film surface of the coating film, or, if swelling does occur, such that it remains within allowable limits. For example, if the overall size of the semiconductor film is less than a maximum size, then this overall size is used as it is as the pattern size for the semiconductor film. If the overall size is greater than the above maximum size, then the semiconductor film is divided into several portions inside a single pixel so that the pattern size of each semiconductor film is made smaller. Once the number and pattern size of a semiconductor film that is placed inside a single pixel are determined in this manner (step S5), then the actual patterning is performed on the semiconductor film formed in step S1 (step S6).

Next, a surface of the semiconductor film 31 patterned in step S6 is oxidized so as to form the insulating film 32a (step S7; second insulating film formation step). Furthermore, the insulating film 32b is formed by a coating method on top of the insulating film 32a (step S8; first insulating film formation step). The gate electrode 33a is then formed by patterning on top of the gate insulating film 32 formed in the manner described above (step S9; gate electrode formation step). As a result, a transistor is manufactured.

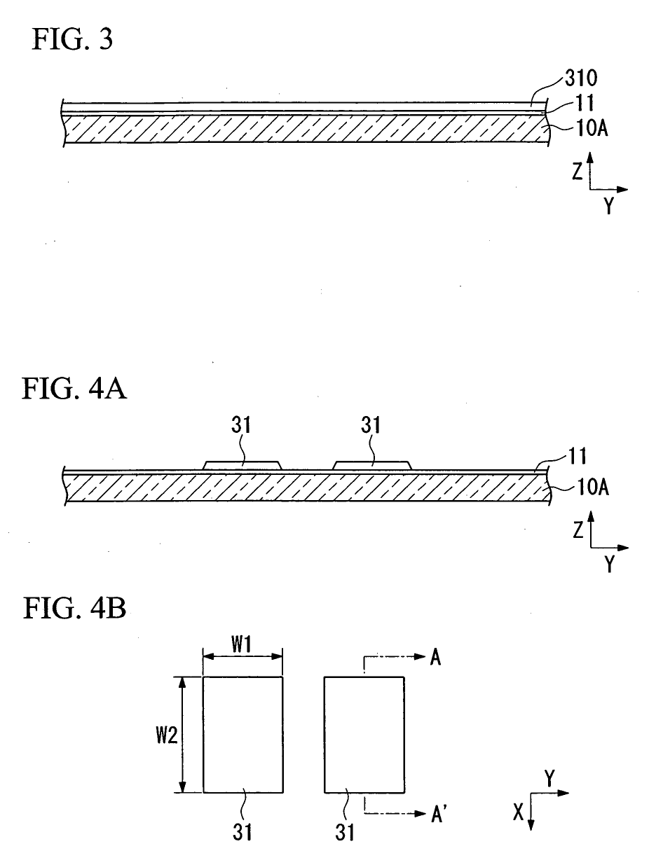

These steps will now be described in detail with reference made to FIGS. 3 to 6C.

Firstly, as is shown in FIG. 3, a base insulating film 11 formed by a silicon oxide film using a plasma CVD method and using tetraethoxysilane (TEOS) and oxygen gas or the like as a base material is formed on a substrate body 10A that is formed from glass or the like. Note that, in addition to a silicon oxide film, as the base insulating film it is also possible to provide a silicon nitride film or a silicon oxide nitride film. This base insulating film 11 is provided in order to adjust the surface condition of the substrate 10A, and also to prevent the semiconductor film 31 from being contaminated by impurities within the substrate 10A, however, it is also possible to omit the base insulating film 11.

Next, using a plasma CVD method or the like, a semiconductor film formed by an amorphous silicon film is formed on the base insulating film 11. This semiconductor film is not limited to an amorphous silicon film and any semiconductor film that contains an amorphous structure such as a microcrystalline semiconductor film may be used. In addition, a compound semiconductor film that contains an amorphous structure such as an amorphous silicon germanium film and the like may be used. Next, a crystallization step such as a laser annealing method or a rapid heating method (i.e., a lamp annealing method or a heat annealing method or the like) is performed on the semiconductor film. As a result, the semiconductor film is crystallized into a polysilicon film (i.e., a semiconductor film formation step). In the laser annealing method, for example, using a line beam having a beam length of 400 mm provided by an excimer laser, the output intensity thereof is set to, for example, 400 mJ/cm². Note that it is also possible to use the second harmonic or third harmonic of YAG laser. It is also possible to scan the line beam such that portions that correspond to 90% of the peak value of the laser intensity in the transverse direction thereof overlap in each area.

Next, as is shown in FIGS. 4A and 4B, the semiconductor film 310 is patterned at a predetermined size (semiconductor film patterning step). At this time, in order to form a film with excellent flatness in the insulating film 32b formation step, which is the subsequent step, in accordance with the above described procedure, the pattern size of the semiconductor film 310 is restricted to within a certain range. For example, in this example, in order to obtain the desired film thickness in the insulating film 32b, the viscosity of the coating solution and the surface tension, as well as the revolution speed of the spin coating and the length of the revolutions are set, and, based on these conditions, the maximum allowable size of the semiconductor film is determined. Specifically, the sizes WI and W2 of sides of the semiconductor film 31 are each set at 50 μm or less. In accordance with this, two semiconductor films 31 are formed by patterning within one pixel. By dividing the semiconductor film so that a plurality thereof can be formed inside a single pixel in this way, it is possible to provide the performance required in the transistor as a whole while reducing the size of each individual semiconductor film 31.

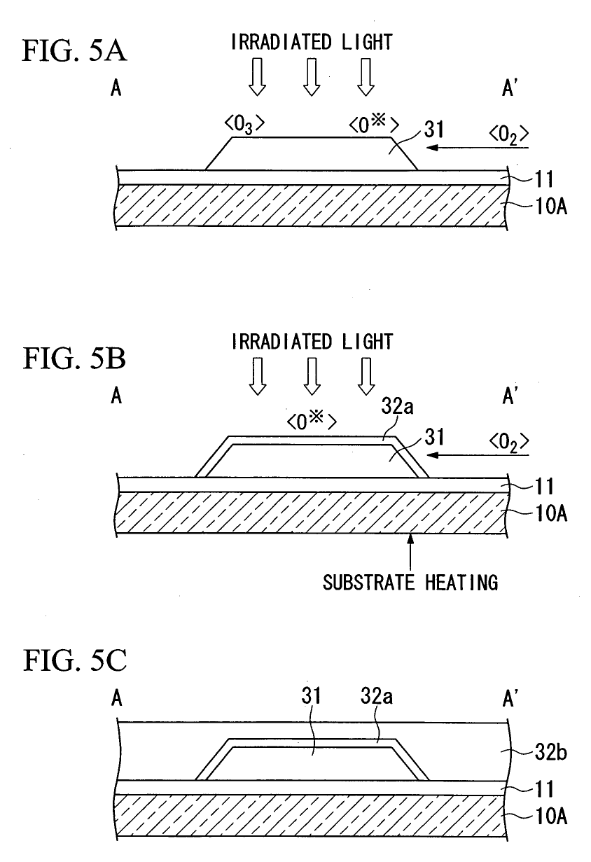

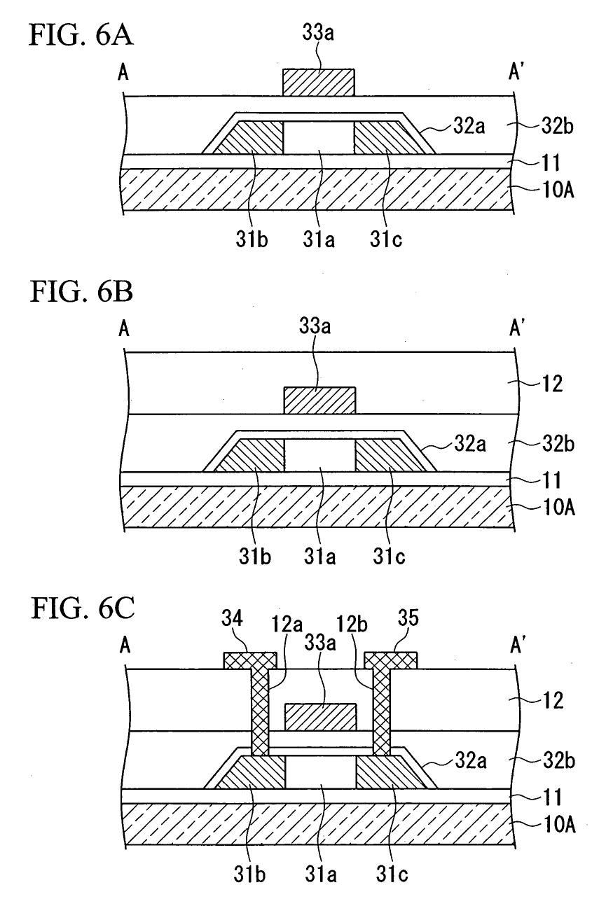

Next, the method of manufacturing a transistor using one semiconductor film 31 shown in FIGS. 4A and 4B will be described based on FIG. 5A to FIG. 6C. Note that FIG. 5A to FIG. 6C are views in which a portion of FIGS. 4A and 4B has been extracted and is shown in a different scale. A portion of the substrate 10 corresponding to a cross-sectional view of the liquid crystal display device shown in FIG. 1B is shown in each step.

When the patterning of the semiconductor film 310 is ended, as is shown in FIG. 5A, UV light is irradiated onto the substrate in an atmosphere of oxygen-containing gas, so that contaminants (e.g., organic substances and the like) present on the substrate surface are decomposed and removed. Here, a low-pressure mercury lamp having a peak intensity at a wavelength of 254 nm, or an excimer lamp having a peak intensity at a wavelength of 172 nm is used for the irradiated UV light. Because light of this wavelength region decomposes oxygen molecules (O₂) into ozone (O₃), and then further decomposes this ozone into oxygen radicals (O*), by using highly active ozone and oxygen radicals created in this way, organic material adhering to the substrate surface can be efficiently removed.

Next, as is shown in FIG. 5B, the substrate is heated to 200° C. to 500° C. In addition, the substrate is irradiated with UV light in an oxygen-containing gas atmosphere so that oxygen radicals (O*) are generated on the substrate. The surface of the semiconductor film 31 is oxidized by these oxygen radicals and the silicon oxide film (i.e., the second insulating film) 32a is formed (the second insulating film forming step). UV light having a peak at a wavelength of 254 nm or less is used for the irradiated UV light. As described above, light of this wavelength region decomposes oxygen molecules (O₂) into ozone (O₃), and then further decomposes this ozone into oxygen radicals (O*). Moreover, light having a wavelength of 175 nm or less directly decomposes oxygen molecules (O₂) and generates oxygen radicals (O*). As a result of oxygen radicals in this active state being created on the substrate surface that has been heated to a high temperature, the surface of the semiconductor film 31 is oxidized and the insulating film 32a is formed.

Here, as the light source for generating the above described UV light, any light source may be used provided that it is able to generate light having the above described wavelength component. For example, light sources having a plurality of line spectrums such as a low-pressure mercury lamp, light sources having a monochrome spectrum such as excimer lamps and excimer lasers, and light sources having a continuous spectrum such as xenon flash lamps and the like may be used. Examples of excimer lasers include krypton fluoride lasers having a central wavelength of 248 nm, and argon fluoride lasers having a central wavelength of 193 nm.

In order to heat the substrate, a resistance heating method such as that using a hotplate may be used, or heating that employs the energy of irradiated light may be used. When the substrate is heated using light energy, light that has a wavelength component suitable for heating a substrate is preferable. By heating the substrate using the energy of irradiated light, an improvement in energy utilization efficiency is achieved. Namely, the energy of light that was not used to create oxygen radicals can be used efficiently to heat the substrate. In addition, other heating apparatuses that use resistance heating or the like are no longer required, so that the apparatus can be further simplified. Note that it is also possible to heat the substrate using a combination of a resistance heating method and a light energy heating method.

In this process, because oxygen radicals are created without plasma being used, there is little damage to the film surface and highly quality boundary faces can be formed between the film surface and the semiconductor film 31. Moreover, in this method, not only is it possible to simplify the apparatus structure compared with when oxygen radicals are created using plasma, but the necessity for the space where the substrate is placed to be in a vacuum pressure is removed, thereby providing the advantage that the processing time can be shortened.

Next, as is shown in FIG. 5C, the silicon oxide film (i.e., the first insulating film) 32b is formed on the insulating film 32a (the first insulating film forming step). This insulating film 32b is formed by first spin coating a coating liquid that has been obtained by mixing polysilazane in xylene on the substrate, and then heat processing the substrate. At this time, the physical properties (i.e., the viscosity and surface tension) of the coating liquid as well as the conditions of the spin coating that are used are those that were decided previously in the aforementioned patterning step. For example, a coating solution obtained by mixing 10% of polysilazane in xylene is spin coated at a revolution speed of 150 rpm, and then prebaking is performed for 5 minutes at a processing temperature of 100° C. Subsequently, further heat processing is performed at a processing temperature of 350° C. for 260 minutes in a WET O₂ atmosphere. As a result, a silicon oxide film having a film thickness of 150 nm is formed. By performing the heat processing in a WET O₂ atmosphere in this manner, it is possible to reduce nitrogen components in the insulating film that are a cause of polarization.

Next, as is shown in FIG. 6A, an electroconductive film for forming a gate electrode that is formed by doped silicon or a silicide film or by a metal such as aluminum (Al), tantalum (Ta), molybdenum (Mo), titanium (Ti), tungsten (W), copper (Cu), chrome (Cr) and the like, or by an alloy containing these metals is formed on the insulating film 32b. Next, the scan lines 33 and the gate electrodes 33a are formed by patterning this electroconductive film (the gate electrode forming step). Note that the gate electrodes 33a may be formed by a single layer electroconductive film, or by a stacked structure.

Next, an impurity element is doped using the gate electrodes 33a as a mask. As a result, the source portion 31 b and the drain portion 31c are formed in the semiconductor film 31 so as to be self-aligning relative to the gate electrode 33a. A region that is covered by the gate electrode 33a but that is not doped by the impurities forms a channel portion 31a.

Next, as is shown in FIG. 6B, the interlayer insulating film 12 is formed so as to cover the gate insulating film 32 and the gate electrode 33a. It is possible to use an insulating film that contains silicon such as, for example, a silicon oxide nitride film or a silicon oxide film as the interlayer insulating film 12.

Next, as is shown in FIG. 6C, a portion of the interlayer insulating film 12 is opened up, and contact holes 12a and 12b are formed respectively at positions corresponding to the source portion 31b and the drain portion 31c of the semiconductor film 31. Next, a metal film such as an aluminum film, a chrome film, or a tantalum film is formed so as to cover inner walls of the contact holes 12a and 12b. By then patterning this metal film, the source electrode (i.e., the signal wire) 34 and the drain electrode (i.e., the intermediate layer) 35 are formed.

By following the above described steps the transistor 30 can be formed.

As is described above, in the present embodiment, because the insulating film 32b is a coated film, bumps and indentations on a substrate created by the semiconductor film patterning step can be flattened by the insulating film 32b. As a result, the film thickness uniformity of the gate insulating film 32 is improved, and a transistor that has high pressure resistance and little current leakage is obtained. In particular, in the present embodiment, after considering the effect of the size of the semiconductor film 31 on the flatness of the coated film, because the pattern size is restricted to within a certain range in advance in the semiconductor film patterning step, the film thickness of the insulating film 32b can be made more uniform.

Moreover, in the present embodiment, because the gate insulating electrode 32 is formed as a stacked film that includes the insulating film 32b as a coating film and the insulating film 32a, which is a surface oxidized film of the semiconductor film 31, the boundary face characteristics between the semiconductor film 31 and the gate insulating electrode 32 are excellent.

(Electronic Instrument)

Next, a specific example of an electronic instrument provided with the liquid crystal device of the present invention will be described.

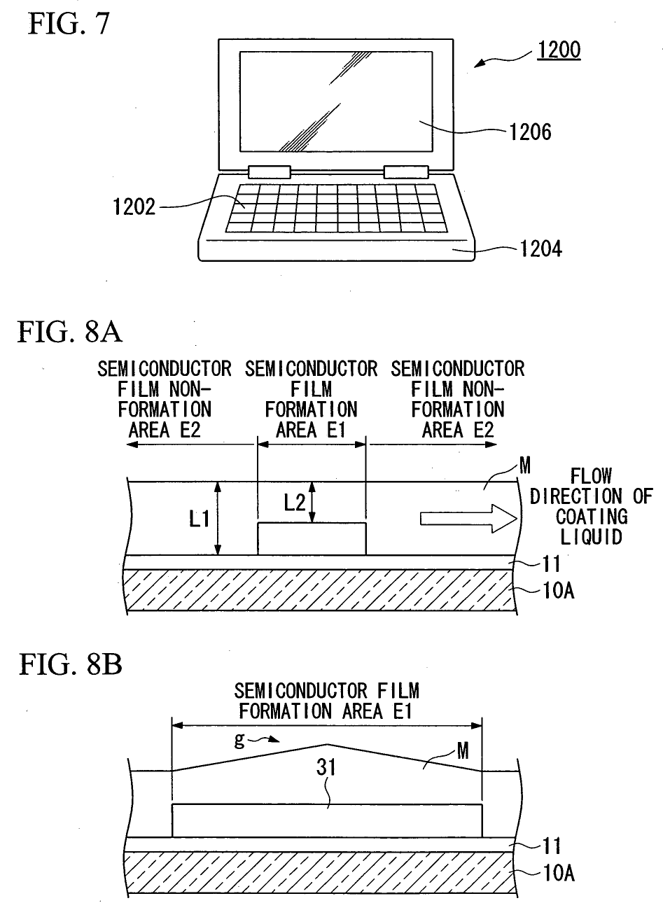

FIG. 7 is a perspective view showing an example of a portable information processing device such as a word processor or personal computer. In FIG. 7, the symbol 1200 represents an information processing apparatus, the symbol 1202 represents an input unit such as a keyboard, the symbol 1204 represents an information processing apparatus main body, and the symbol 1206 represents a display unit that uses the aforementioned liquid crystal device.

Because the electronic instrument shown in FIG. 7 is provided with a display unit that uses the liquid crystal device of the above described embodiment, a high quality display is possible by using reliable switching.

Note that the present invention is not limited to the above described embodiment and various modifications may be made thereto insofar as they do not depart from the purpose of the present invention.

For example, in the above described embodiment, the gate insulating film 32 has a two layer structure formed by the surface oxidized film 32a of the semiconductor film 31 and the insulating film 32b, which is a coating film, however, the gate insulating film may also be formed as a multilayer structure having three or more layers. For example, by forming a third insulating film at the boundary face between the gate insulating film 32 and the gate electrode 33a using a vapor deposition method or the like, it is possible to stabilize the electrical characteristics of the transistor even more. Naturally, if excellent boundary face characteristics can be obtained using only the first insulating film 32b, then it is possible to omit the second insulating film 32a and the aforementioned third insulating film, and to form the gate insulating film 32 using a single layer structure formed only by the insulating film 32b.

Furthermore, in FIGS. 4A and 4B, an example is described in which the semiconductor film is formed by being divided into two inside a single pixel, however, instead of this, it is also possible to divide the semiconductor film into three or more portions. Naturally, if the overall size of the semiconductor film determined in step S2 of FIG. 2 is sufficiently small, then the semiconductor film can be provided whole in an undivided form.

Moreover, in the above described embodiment, a liquid crystal device is described as an example of an electro-optic device, however, in addition to this, the present invention can be applied to various devices such as, for example, organic EL display devices and electrophoretic display devices.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as limited by the foregoing description and is only limited by the scope of the appended claims.

1. A method of manufacturing a transistor comprising the steps of:
forming a semiconductor film over a substrate;
patterning the semiconductor film in an island configuration;
forming a gate insulating film on the semiconductor film; and
forming a gate electrode on the gate insulating film, wherein
forming the gate insulating film comprises forming a first insulating film that constitutes at least a portion of the gate insulating film by a coating method.

2. The method of manufacturing a transistor according to claim 1, wherein patterning the semiconductor film comprises setting a pattern size of the semiconductor film in accordance with properties of a coating liquid used in forming the first insulating film, coating conditions, and a film thickness required for the first insulating film.

3. The method of manufacturing a transistor according to claim 2, wherein patterning the semiconductor film comprises setting a maximum allowable size of the semiconductor film in accordance with properties of the coating liquid used in forming the first insulating film, the coating conditions, and the film thickness required for the first insulating film; determining an overall size of the semiconductor film based on a performance required in a transistor; and dividing, if the overall size is greater than the maximum size, the semiconductor film into a plurality of portions such that the size of each portion of the semiconductor film is less than or equal to the maximum size.

4. The method of manufacturing a transistor according to claim 1, wherein forming the first insulating film is by spin coating method.

5. The method of manufacturing a transistor according to claim 1, wherein forming the first insulating film comprises coating polysilazane on the semiconductor film, and then converting the polysilazane into silicon oxide by heat processing.

6. The method of manufacturing a transistor according to claim 5, wherein the heat processing is performed in a WET O₂ atmosphere.

7. The method of manufacturing a transistor according to claim 1, wherein forming the gate insulating film comprises forming, before forming the first insulating film, a second insulating film that constitutes a portion of the gate insulating film by oxidizing a surface of the semiconductor film.

8. The method of manufacturing a transistor according to claim 7, wherein forming the second insulating film is by performing plasma processing on the surface of the semiconductor film using a gas that contains oxygen.

9. The method of manufacturing a transistor according to claim 7, wherein forming the second insulating film is by irradiating ultraviolet light onto the semiconductor film in an oxygen-containing gas atmosphere.

10. The method of manufacturing a transistor according to claim 1, wherein forming the gate insulating film comprises forming a second insulating film that constitutes a portion of the gate insulating film by a vapor deposition method at a boundary face with the semiconductor film or a boundary face with the gate electrode.

11. An electro-optic device comprising a transistor manufactured by the method according to claim 1.

12. An electronic instrument comprising the electro-optic device according to claim 11.

13. A transistor manufactured by the method according to claim 1.
